(19) United States
(12) Patent Application Publication
(10) Pub. No.: US 2016/0120053 A1
(43) Pub. Date: Apr. 28, 2016

(54) STORAGE AND PROTECTION CASE FOR A THUMB DRIVE

(71) Applicant: Robert J. Curnock, Waco, TX (US)

(72) Inventor: Robert J. Curnock, Waco, TX (US)

(21) Appl. No.: 14/922,060

(22) Filed: Oct. 23, 2015

Related U.S. Application Data
(60) Provisional application No. 62/068,051, filed on Oct. 24, 2014.

(51) Int. Cl. H05K 5/02; B65D 25/10

(52) U.S. Cl. CPC H05K 5/0286; B65D 25/10; H05K 5/0252

(57) ABSTRACT

A storage device and method for storing, protecting, and cataloging a thumb drive.

### STATEMENT OF PRIORITY

The present application claims priority to U.S. Provisional Application No. 62/068,051, titled “Storage and Protection Case For a Thumb Drive” and filed Oct. 24, 2014.

### TECHNICAL FIELD

The present disclosure relates to media storage and protection devices.

### BACKGROUND

USB-based flash memory storage devices (“thumb drives”) are increasingly the storage medium of choice for digital data back-up. This is because of their affordability, durability, and versatility, as opposed to, for example, hard drives. In addition to uses for back-up purposes, thumb drives are also (among many other purposes) ideal for sharing of information between computer users, especially with respect to data that is not suitable for on-line transmission (for security reasons, for example). Further still, there exist some circumstances in which, even if security, costs, and the like in no way urge way from use of hard drives, on-line transmissions, or other data storage and transmission options, to have tangible repository for such data. For example, a business that wants to provide promotional information, electronic product offerings or catalogs, instructional materials, and the like, may want to achieve the visual reminder aspect of providing such data in a tangible form, such as a thumb drive with the businesses name, logo and the like.

As desirable as thumb drives are, dependence on them has certain, current disadvantages. As one collects a number of thumb drives (as is increasingly the norm), the thumb drives resemble in appearance and there is risk of loss or confusion, as is the case with any collection of effectively indistinguishable repositories of information or other items (such as a collection of unlabeled CD, DIVs, unmarked boxes, and the like). This, because there currently exists no effective means for labeling, organizing, or otherwise readily identifying data that resides on a thumb drive. While one may, in theory mark a thumb drive's exterior with an indelible marker to indicate its contents, in practice, virtually no one actually does this (despite the best of intentions, perhaps, to later do so, or based on a passing belief that one will simply recall what is stored on a thumb drive).

Furthermore, even if one exhibits the discipline to label thumb drives, there still exists no option for organizing subsets of one's collections, readily identifying such collection, nor for physically protecting or displaying such drives (in bookcase fashion for overall organization and easy location). Certainly, one can store thumb drives in any box or other container, but without specific accommodation for organizing, segregating, and protection the thumb drives, the container becomes just another disorganized assemblage with out benefit in identifying, organization, displaying, or protecting the thumb drives.

Another branch of impeding growth in the use of thumb drives is in the motion picture sales and rental market. As audio-visual entertainment continues its migration to computer-based implementation, and DVDs are likely to go the way of VHS tapes. The natural alternative is the use of thumb drives to distribute motion pictures in the sales and rental market, in part, because any computer with the capacity to play a high definition motion picture will also have at least one (mostly likely more) USB ports in which a thumb drive can be plugged into.

### SUMMARY OF THE INVENTION

In view of the foregoing, there is a considerable need for, and it will well serve all users of thumb drives to provide a storage device method for storing, organizing, displaying, and identifying the contents thumb drives. Such a storage device and associated method of use would ideally include means for maintaining a thumb drive in a physically protected enclosure. Furthermore, the enclosure would ideally lend itself to display of identifying or promotional media, particularly in the case of motion picture distribution, where attractive and informative inserts would resemble those of today's DVD cases.

In satisfaction of these and related needs and objectives, the present inventor has designed a thumb drive storage device that is configured specifically to accommodate a thumb drive, to provide for use of externally viewable, and to provide physical protection from impact and soiling from dust, and the like, while also facilitating ease of repeated removal form, and replacement within such enclosure.

### BRIEF DESCRIPTION OF THE DRAWINGS

The following figures are included to illustrate certain aspects of the present invention, and should not be viewed as an exclusive embodiments. The subject matter disclosed is capable of considerable modification, alteration, and equivalents in form and function, as will occur to one having ordinary skill in the art and the benefit of this disclosure.

FIG. 1 is a perspective view of the preferred embodiment of the thumb drive storage unit of the present invention.

FIG. 2 is a perspective view of the unit of FIG. 1, opened to show the interior configuration of such unit.

### DETAILED DESCRIPTION

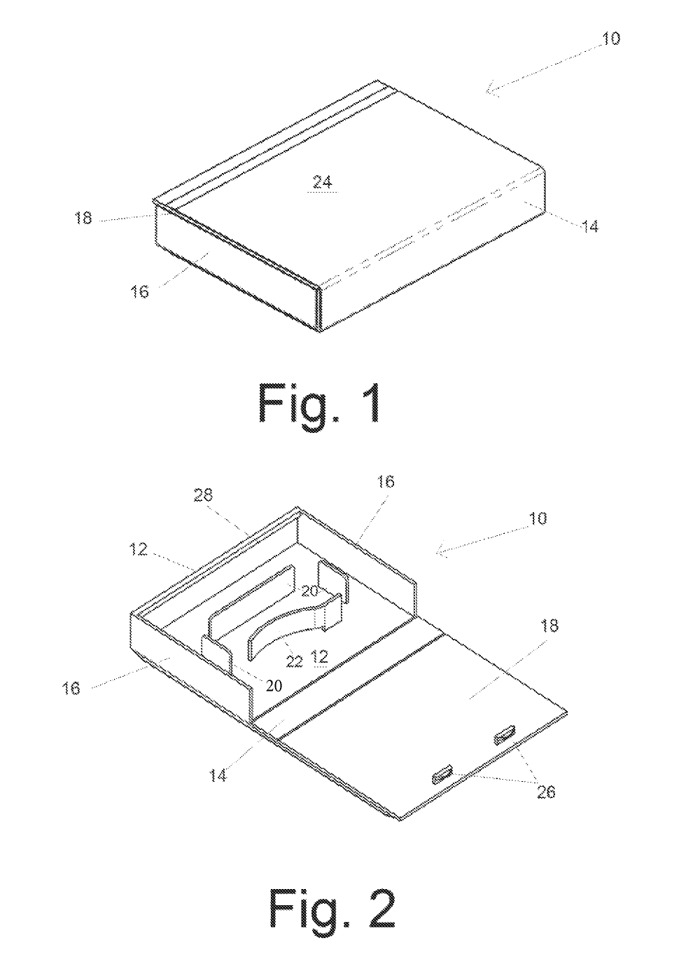

Referring to FIGS. 1 and 2, the thumb drive storage device of the present invention is identified generally by the reference numeral 10. Device 10 is a book-like-shaped enclosure with back cover wall 12, a spine wall 14, end walls 16, and a front cover wall 18. Device 10 is, in the preferred embodiment, fabricated of substantially rigid plastic, but could, of course, be fabricated from any number of substantially rigid and long-lasting materials (such as metal).

Situated within the interior space of device 10 is a thumb drive support assembly that includes, in the preferred embodiment, three rigid delimiters 20 and a yieldable tab 22. The curved portion of tab 22 is, of course, detached from the underlying case structure, such that it can “bend” slightly to accommodate the insertion or removal of a thumb drive. The combination of delimiters 20 and yieldable tab 22 define a thumb drive space therein, and provide for secure maintenance of an enclosed thumb drive, accommodation of variations of thumb drive dimensions, and for ready removal and replacement of a thumb drive.

In one embodiment, a substantially transparent cover 24 is fixed to the exterior of one or all of back cover wall 12, spine wall 14, and/or front cover wall 18. One or more margins of cover 24 are left unattached to the underlying device material, such that labels or other indicia-bearing media can be inserted and removed as a user as identifying information relative to the thumb drive contained in device 10 (similar to conventional DVD case labeling that is well known in the art).

Snap tabs 26 ar provided on the inside surface of front cover wall 18, with compatible slot(s) 28 being formed in back cover wall 12 to provide reversible snap-fit closure of device 10.

As previously mentioned, one need addressed by the present invention is that of providing storage means that are specifically directed to a thumb drive. Therefore, dimensions of the various components of the device 10 are important. For example, for a device 10 configured for storing a thumb drive, the dimensions described hereafter are considered ideal, with slight variations still, of course, residing within the scope for the present inventions. Configured substantially according to the recited dimensions, device 10 will achieve all of the stated objectives of accommodating a thumb drive, and providing physical protection from impact and soiling from dust, and the like.

Accordingly, in one embodiment, device 10 is approximately 3-½″×3″×¾. Cover 26, in the preferred embodiment, accommodates media that is approximately 3″×3-¾″, such that conventional business card-sized media (not shown in the drawings) may be used as the indicia media. The thumb drive space defined by the delimiters 20 and yieldable tab 22 may be, in at least one embodiment, dimensions of approximately ⅞″×⅝″×3″.

Although the invention has been described with reference to specific embodiments, this description is not meant to be construed in a limited sense. Various modifications of the disclosed embodiments, as well as alternative embodiments of the inventions will become apparent to persons skilled in the art upon the reference to the description of the invention. It is, therefore, contemplated that the appended claims will cover such modifications that fall within the scope of the invention.

What is claimed is:

1. A device for storing a thumb drives comprising:
an enclosure having a front cover wall, a back cover wall, a spine wall, and first and second end walls that collectively defined an interior space, at least one of said front cover wall, back cover wall, spine wall, and first and second end walls for facilitating reversible closure of said interior space; and
a thumb drive support assembly positioned within said interior space, said support assembly including a plurality of delimiters, and at least one yieldable tab member, said plurality of delimiters and said yieldable tab member defining a thumb drive space within said interior space for snugly accommodating a thumb drive.

2. The device of claim 1 wherein said thumb drive space has dimensions of approximately ⅞″×⅝″×3″.

3. The device of claim 1 further comprising a substantially transparent indicia retaining means attached to said enclosure for reversibly inserting, maintaining, and displaying indicia means.

4. The device of claim 2 further comprising a substantially transparent indicia retaining means attached to said enclosure for reversibly inserting, maintaining, and displaying indicia.

5. The device of claim 1, wherein said cover wall further comprises a snap tab on an inside surface thereof, and wherein said back cover wall further comprises a slot configured to accept said snap tab.

6. A method for storing a plurality of thumb drives comprising the steps of:
selecting an enclosure having a front cover wall, a back cover wall, a spine wall, and first and second end walls that collectively defined an interior space, at least one of said front cover wall, back cover wall, spine wall, and first and second end walls being reversibly engaged with one or more of the remaining said front cover wall, back cover wall, spine wall, and first and second end walls for facilitating reversible closure of said interior space, said enclosure further having a thumb drive support assembly positioned within said interior space, said support assembly including a plurality of delimiters and at least one yieldable tab member defining a thumb drive space for snugly accommodating a thumb drive; and
inserting a thumb drives into said thumb drive space, and effecting said closure of said interior space.

7. The method of claim 6, wherein said thumb drive space has dimensions of approximately ⅞″×⅝″×3″.

8. The method of claim 6 wherein said enclosure further comprises a substantially transparent indicia retaining means attached to said enclosure for reversibly inserting, maintaining, and displaying indicia, and further comprising the step of inserting indicia into said indicia retaining means.

9. The method of claim 7 wherein said enclosure further comprises a substantially transparent indicia retaining means attached to said enclosure for reversibly inserting, maintaining, and displaying indicia, and further comprising the step of inserting indicia into said indicia retaining means.

10. The method of claim 6, wherein closure of said interior space is reversibly effected via a snap tab on an inside surface of said cover wall and a slot of said back cover configured to accept said snap tab.
